(19) United States
(12) Patent Application Publication
(10) Pub. No.: US 2023/0399533 A1
(43) Pub. Date: Dec. 14, 2023

(54) CONDUCTIVE AQUEOUS INK COMPOSITION FOR FILLING IN ENGRAVED MICROPATTERN, CONDUCTOR-FILLED MICROPATTERN FABRICATED USING SAME, AND CONDUCTIVE DEVICE INCLUDING SAME

(71) Applicant: DAEDONG CO., LTD., Busan (KR)

(72) Inventors: Seung Taeg LEE, Busan (KR); Cheol Joo LEE, Busan (KR); Hee Jung NOH, Busan (KR); Gyeong Min KIM, Busan (KR); Ji Yong LEE, Busan (KR)

(73) Assignee: DAEDONG CO., LTD., Busan (KR)

(21) Appl. No.: 18/031,882

(22) PCT Filed: Oct. 5, 2021
(86) PCT No.: PCT/KR21/13553

§ 371 Date: Apr. 14, 2023

(30) Foreign Application Priority Data
Oct. 16, 2020 (KR) 10-2020-0133874

(51) Int. Cl. C09D 11/52; C09D 11/037; C09D 11/033; H05K 1/02; H05K 1/09; H05K 3/10

(52) U.S. Cl. CPC C09D 11/52; C09D 11/037; C09D 11/033; H05K 1/0296; H05K 1/092; H05K 3/10

(57) ABSTRACT

The present disclosure relates to a conductive aqueous ink composition for filling in an engraved micropattern, conductor-filled micropatterns fabricated using same, and a conductive device comprising same, wherein the conductive aqueous ink composition is conductive aqueous ink to be used for filling in an engraved micropattern formed on a substrate and can be applied to plastic bases, etc., and improve working environments due to low temperature sintering. The ink composition comprises: metal nanoparticles (A) protected by a dispersion stabilizer and ranging in particle size from 5 to 50 nm, metal particles (B) ranging in particle size from 100 to 900 nm; and a water-soluble solvent (C) having a boiling point of at least 150° C., the dispersion stabilizer containing a protective polymer composed of branched polyalkylene imine segments and polyoxyalkylene segments and an amine acid salt composed of an amine and an inorganic acid.

### TECHNICAL FIELD

The present disclosure relates to a conductive aqueous ink composition for filling in an engraved micropattern formed on a substrate, which can be applied to plastic substrates due to low temperature calcining thereof and can improve the working environment, to a conductor-filled micropattern fabricated using the same, and to a conductive device including the same.

### BACKGROUND ART

The manufacture of printed wiring board semiconductor devices and ultra-micro wiring is mostly manufactured through a photolithography process. In this case, since a complex multi-step manufacturing process is performed, a technique for forming a high-density microcircuit at low cost in circuit wiring manufacturing of electronic devices has recently been required. For example, according to high-density multi-layering, the via wiring that connects each layer through via-holes opened between other layers is formed by filling with conductive ink. In addition to filling via-holes, a method of forming a wiring pattern is also being considered to form a trench with a micro line width and depth of several μm on a substrate such as a semiconductor base or metal mesh pattern and to form a wiring pattern on the trench by filling with conductive ink.

In the future, the diameter of the via-hole and the line width and depth of the trench are expected to be less than several tens of μm or several μm due to the further demand for high-density multilayering. In order to prepare such a micropattern, conductive ink made of metal nanoparticles having good conductivity and micropattern-filling properties has been developed. Conductive ink containing metal nanoparticles such as gold, silver, platinum, copper, etc., can be used as the conductive material ink used for micro wiring filling such as high-density multilayer. Silver nanoparticles and silver nanoparticle ink have been developed in advance with good conductivity, economy, and ease of handling.

In addition, when the metal size of the silver nanoparticles becomes smaller than the nano unit size, the specific surface area of the silver nanoparticle becomes much larger than that of bulk silver, and surface energy increases, so there is a strong tendency to degrade surface energy by mutual fusion. As a result, the particles are easily fused at a temperature much lower than the melting point of bulk silver due to the quantum size effect. Accordingly, there is an advantage of using silver nanoparticles as a conductive material. However, since the easy-to-fuse property of metal nanoparticles makes it difficult to stabilize the metal nanoparticles and thus degrades dispersion stability, it is necessary to stabilize the metal nanoparticles and protect them with a dispersion stabilizer to prevent fusion. Accordingly, a metal mesh method is known as a method of forming conductive wiring on a general-purpose plastic such as polyethylene terephthalate (PET) or polyethylene naphthalate (PEN), which are cheap and low in heat resistance but are easy to form thin film flexibly, by forming a micropattern by a printing method of filling into a via hole or trench groove using conductive aqueous ink for filling in an engraved micropattern, in which the ink is composed of nanometer-sized silver particles, and calcining at a low temperature of 150° C. or less.

Meanwhile, as awareness of environmental issues and product safety has recently increased, regulations on chemical substances have become stricter, and there is a strong tendency to regulate the total amount of emissions in the industry and suppress the emission of chemical substances. In relation to this, compared to oil-based ink, which is a petroleum-based solvent, aqueous ink is non-flammable and safe, resource-rich, and economical. The use of aqueous ink due to these advantages and according to the regulation of harmful chemicals is essentially required. In addition, if the liquid medium of the conductive ink for filling micropattern uses water-based, mainly water, rather than oil-based, mainly organic solvent, the working environment can be well managed when printing, and the risk of fire or explosion can be reduced, so the use of aqueous ink is further required.

In addition, as is well known in the metal mesh method, etc., the method of forming an engraved micropattern by filling is performed by forming a micropattern by filling a trench groove or via-hole formed on a base with conductive ink for filling, and then heating, calcining, and removing metal particles remaining on a substrate. In the method of filling the conductive ink in the trench groove or the base on which the via-hole, a conductive ink for filling is placed on one front end on a base mounted on a filling device, a force is applied to a doctor blade, etc., and the doctor blade pushes the conductive ink for filling to the other end and allows the conductive ink to fill in a trench groove or via-hole. Therefore, it is important to adjust the composition of the conductive ink for filling and the viscosity of the ink in order to satisfactorily fill the trench groove or via-hole in the formation of the engraved micropattern by filling. For example, in patent reference 1, the composition of the conductive ink for filling was adjusted using mostly μm silver particles for low volume change after calcining and good filling on micropatterns, but due to the particle size, it is difficult to fill on micropatterns below a few μm, and it cannot be used on plastic bases with weak heat resistance due to the high calcining temperature of 600° C. In addition, Patent Document 2 proposes a conductive ink for filling using copper nanoparticles instead of silver nanoparticles, but there is a limitation in that the conductive ink must be filled under pressurized conditions, reducing conditions using hydrogen gas dangerous for safety, the high calcining temperature of 200° C., and a large amount of solvent such as flow paraffin, resulting in low conductivity and problems with the environment that uses an organic solvent. Therefore, there is a need for a conductive aqueous ink for filling in an engraved micropattern, which may manufacture a good conductive micro wiring on a plastic base with low heat resistance by calcining at a low temperature below 150° C. and may be easily filled in the engraved micropattern formed on the substrate.

Accordingly, the inventors of the present disclosure focused on the above technical requirements and researched and reviewed the results. As a result, a conductive aqueous ink composition capable of expressing good conductivity in low temperature calcining and excellent work environment management was developed, and the present disclosure was completed while being used to manufacture a conductive device by easy filling in an engraved micropattern formed on a substrate.

### DISCLOSURE

### Technical Problem

Therefore, a technical solution of the present disclosure is to provide a conductive aqueous ink composition for filling in an engraved micropattern formed on a substrate, which may be easily filled to a plastic base by low temperature calcining and may improve a working environment due to an aqueous ink while exhibiting good conductivity, in which the composition contains metal nanoparticles protected by a dispersion stabilizer, metal particles having a slightly larger average particle diameter, and a water-soluble solvent.

Another technical solution of the present disclosure is to provide a conductor-filled micropattern fabricated using the conductive aqueous ink composition for filling in the engraved micropattern.

The other technical solution of the present disclosure is to provide a conductive device including the conductor-filled micropattern.

### Technical Solution

In order to solve the above technical problem, the present disclosure provides a conductive aqueous ink composition for filling in an engraved micropattern, the composition including: metal nanoparticles (A) protected with a dispersion stabilizer

and having a particle size in the range of 5 to 50 nm; metal particles (B) having a particle size in the range of 100 to 900 nm; and a water-soluble solvent (C) having a boiling point of at least 150° C.; in which
the above dispersion stabilizer includes: protective polymers composed of branched polyalkylene imine segments and polyoxyalkylene segments; and aminates composed of amine and inorganic acids.

In the present disclosure, the solid content of the combined metal nanoparticles (A) and metal particles (B) is at least 70% by weight, and the water-soluble solvent (C) may be at least one selected from an alkylene glycol-based solvent or glycerin.

In addition, in the present disclosure, the metal nanoparticles (A) and the metal particles (B) are silver nanoparticles and silver particles.

In addition, in the present disclosure, the engraved micropattern is a via or a trench, in which
the diameter and depth of the via-hole and the width and depth of the trench are in a range of 0.5 to 10 μm, respectively.

In addition, the present disclosure in order to solve the other technical problems described above

provides a conductor-filled micropattern that is manufactured by filling and calcining the above-described conductive aqueous ink composition for filling in the engraved micropattern formed on the substrate.

In addition, the present disclosure, in order to solve the other technical problems described above, provides a conductive device including the conductor-filled micropattern.

Advantageous Effects

The conductive aqueous ink composition for filling in an engraved micropattern obtained in the present disclosure exhibits good conductivity as well as good low temperature calcining properties. The expression of such low temperature plasticity and good conductivity is because a protective stabilizer for metal nanoparticles composed of a mixture of polymer with branched polyalkylene imine segments and polyoxyalkylene segments and low molecular aminates is easily separated from the surface of the metal nanoparticles at low temperatures, and then the activated metal nanoparticles are firmly fused to surround the metal particles having a larger average particle diameter. In addition, by using metal particles having a larger particle diameter together with the metal nanoparticles, there is an effect of exhibiting a good filling property of the engraved micropattern.

In addition, unlike the conventional oil-based ink composition, the conductive aqueous ink composition for filling in an engraved micropattern of the present disclosure does not dissolve or swell general-purpose plastic substrates, has no odor or toxicity, does not worsen the working environment, and has no risk of fire or explosion.

Therefore, the conductive aqueous ink composition for filling in an engraved micropattern of the present disclosure is easily filled in the engraved micropattern formed on a substrate and exhibits technical effects capable of forming circuit wiring or the like that exhibits good conductive performance by calcining at a low temperature compared to the related art.

### DESCRIPTION OF DRAWINGS

FIG. 1 shows an exemplary diagram of an engraved micropattern according to an embodiment of the present disclosure;

FIG. 2 shows an exemplary diagram of filling a conductive aqueous ink composition in an engraved micropattern according to an embodiment of the present disclosure;

FIG. 3 shows a TEM image of silver nanoparticles prepared according to an embodiment of the present disclosure;

FIG. 4 shows a SEM image of the cross-section of a micro wiring fabricated according to Example 1 of the present disclosure;

FIG. 5 shows a SEM image of the surface of the micro wiring fabricated according to Example 1 of the present disclosure;

FIG. 6 shows a SEM image of silver nanoparticles prepared according to a Comparative Example 1 of the present disclosure;

FIG. 7 shows a SEM image of silver nanoparticles prepared according to a Comparative Example 2 of the present disclosure; and

FIG. 8 shows a SEM image of the cross-section and surface of a micro wiring fabricated according to Comparative Example 2 of the present disclosure.

### BEST MODE

Hereinafter, the present disclosure will be described in more detail.

The present disclosure relates to a conductive aqueous ink composition for filling in an engraved micropattern, the conductive aqueous ink composition includes: metal nanoparticles (A) protected with a dispersion stabilizer and having a particle size in a range of 5 to 50 nm; metal particles (B) having a particle size in a range of 100 to 900 nm; and water-soluble solvent (C) having a boiling point of at least 150° C. The dispersion stabilizer included in the composition of the present disclosure includes: a protective polymer composed of branched polyalkylene imine segments and polyoxyalkylene segments; and an aminate composed of an amine and an inorganic acid, thereby exhibiting high dispersion stability and protecting the metal nanoparticles (A) to exhibit good conductivity even in low temperature calcining, and the engraved micropattern filling property may be well exhibited by using the metal particles (B) having a larger particle diameter together with the metal nanoparticles (A). That is, in the present disclosure, a dispersion stabilizer of metal nanoparticles composed of a mixture of a polymer having branched polyalkylene imine segments and polyoxyalkylene segments and an aminate is easily separated from the surface of the metal nanoparticles at low temperatures. Since then, the activated metal nanoparticles (A) have been firmly fused to exhibit good low temperature plasticity and good conductivity, and the metal nanoparticles (B) with larger particle diameter and the metal nanoparticles (A) can exhibit good filling properties for engraved micropattern.

In the present disclosure, the polyalkylene imine segment (a) in the protective polymer constituting the dispersion stabilizer is a segment capable of immobilizing a metal into nanoparticles because the nitrogen atom part of the alkylene imine may be coordinated covalent bonded with a metal or metal ion. Accordingly, when the metal nanoparticles protected with the protective polymer of the present disclosure are prepared or stored in a hydrophilic solvent, the polyalkylene imine segment (a) and the polyoxyalkylene segment (b) have hydrophilicity and the polyalkylene imine segment (a) is immobilized on the surface of the metal nanoparticles by forming a coordinate covalent bond with the metal, whereas the polyoxyalkylene segment (b) moves freely in the solvent and becomes a repulsive force between the metal nanoparticles, resulting in excellent dispersion stability and storage stability in the resulting metal colloidal solution.

The number of alkylene imine units in the polyalkylene imine segment (a) is not particularly limited, but when the number of units is too small, the protective ability of the metal nanoparticles as a protective polymer is likely to be insufficient, whereas when the number of units is too large, the particle diameter of the metal nanoparticles composed of metal nanoparticles and the protective polymer is easy to increase, which hinders dispersion stability.

Accordingly, in consideration of the immobilization ability of the metal nanoparticles or the ability to prevent the macro-enlargement of the nanoparticles, the number of alkylene imine units in the polyalkylene imine segment (a) is usually in the range of 10 to 5,000, more preferably 100 in the range of 100 to 2,000.

In addition, the polyalkylene imine segment (a) includes branched polyalkylene imine among linear polyalkylene imine containing only secondary amines and branched polyalkylene imine containing primary, secondary, and tertiary amines, and in this disclosure, it can be used without particular limitation as long as it is commercially available or synthesized. Preferably, since metal nanoparticles may be dispersed in solvent compositions of various polarities by controlling the degree of polarity by the kind or number of introduced functional groups, and thus branched polyalkyleneimine may preferably be used. More preferably, branched polyethylene imine or branched polypropylene imine is preferable in consideration of being easily obtained industrially, and in particular, branched polyethylene imine is even more preferable.

The weight-average molecular weight of the protective polymer composed of the polyalkylene imine segment (a) and the polyoxyalkylene segment (b) is not particularly limited, but when a hydrophilic medium is used, if the weight-average molecular weight of the protective polymer is too small, dispersion stability deteriorates due to reduced protective capacity of metal nanoparticles as a protective polymer, on the other hand, if the weight-average molecular weight of the protective polymer is too large, since the nanoparticles are agglomerated, the particle diameter or stability of the metal nanoparticles in the colloidal solution is hindered. Therefore, the weight-average molecular weight of the protective polymer composed of the polyalkylene imine segment (a) and the polyoxyalkylene segment (b) is usually in the range of 500 to 150,000 and more preferably in the range of 1,000 to 100,000.

The polyoxyalkylene segment (b) is a segment that exhibits high affinity with a solvent and maintains the storage stability of the colloidal solution when a hydrophilic medium such as water is used as the metal colloidal aqueous solution. The polyoxyalkylene segment (b) can be used without particular limitation as long as it is generally commercially available or synthesized. In particular, when a hydrophilic solvent is used, a colloidal solution excellent in stability may be obtained, and thus the polyoxyalkylene segment is preferable to be made of a nonionic polymer.

As the polyoxyalkylene segment (b), for example, a polyoxyethylene segment or a polyoxypropylene segment is preferred, and a polyoxyethylene segment is preferred from the viewpoint of industrial availability.

In addition, low molecular weight amines produced by the aminate exchange between the polyalkyleneimine and the aminate can be immobilized on the surface of the metal nanoparticles by forming a coordinate covalent bond with the metal, thereby contributing to the improvement of dispersion stability in aqueous solution. At this time, the low molecular amine may have a boiling point in the range of 180° C. or less, and more preferably may have a boiling point in the range of 130° C. or less. This is because low molecular amines generated by the aminate exchange between polyalkylene imine and low molecular aminates are easily removed at low temperatures when filling a micropattern on a substrate with a conductive material obtained by adjusting a dispersion of metal nanoparticles, that is, a metal colloidal aqueous solution or an aqueous solution thereof, with conductive ink for filling in an engraved micropattern and then calcining at a low temperature, resulting in contributing to the improvement of conductivity performance. Therefore, in the present disclosure, the amine is a low molecular amine that can be easily removed at low temperatures and has a boiling point of 130° C. or less, for example, and may include methylamine, dimethylamine, methylethylamine, ethylamine, diethylamine, propylamine, isopropylamine, butylamine, isobutylamine, pentylamine and the like. In addition, the low molecular weight aminate (c) containing the low molecular weight amine may include, for example, hydrochloric acid, nitric acid, sulfuric acid, etc., as an inorganic acid.

In addition, as described above, the dispersion stabilizer of the metal nanoparticles includes a polyoxyalkylene segment (b), and a low molecular weight aminate (c) in addition to the polyalkylene imine segment (a) of the protective polymer allowing the metal nanoparticles to exist in a stable state. As described above, the polyoxyalkylene segment (b) exhibits good affinity with the solvent in a hydrophilic solvent. At this time, when the number of alkylene imine units in the polyalkylene imine segment (a) is in the range of 100 to 2,000, the use ratio of the protective polymer composed of the branched polyalkylene imine segment (a) and the polyoxyalkylene segment (b) and the low molecular weight aminate (c) in the mixture is determined by adjusting the amine equivalent of the low molecular weight aminate (c) to the amine equivalent of the polyalkylene imine segment (a), thereby improving good conductivity and dispersion stability at low temperature calcining. At this time, preferably, the amine equivalent of the low molecular aminate (c) with respect to one equivalent of the amine of the polyalkylene imine segment (a) may be in the range of 0.1 to 1.0 equivalents, and more preferably in the range of 0.1 to 0.7 equivalents.

In addition, the metal nanoparticle protective polymer of the present disclosure composed of the branched polyalkylene imine segment (a) and the polyoxyalkylene segment (b) cannot sufficiently protect the metal nanoparticles when the metal nanoparticle protective polymer is used in an excessively small amount, resulting in a good particulate metal colloidal aqueous solution cannot be obtained, but when the metal nanoparticle protective polymer is used in an excessively large amount, unnecessary dispersion stabilizers are overused. In the separation and purification process of metal nanoparticles, the excess dispersion stabilizer interferes with the separation, thereby deteriorating the purification separability. Therefore, in the metal nanoparticle protective polymer of the present disclosure, the amount of the metal nanoparticle dispersion stabilizer is not particularly limited but is desirably 2% to 15% by weight, more desirably 3% to 10% by weight, of the metal nanoparticles obtained from the viewpoint of dispersion stability, preservation stability, and good conductive performance of the metal colloidal aqueous solution obtained by synthesis.

In the method of manufacturing metal nanoparticles (A), which are important components of the conductive aqueous ink for filling in the engraved micropattern of the present disclosure, the metal nanoparticles (A) may be manufactured, for example, by adding and reducing a small amount of metal ions into a solvent of a polymer, adding the remaining amount of metal ions again after a predetermined time and reducing to obtain metal nanoparticles, adding an appropriate poor solvent, precipitating, and separating the metal nanoparticles, thereafter, adding a low molecular weight aminate (c) to a concentrated solution of the separated metal nanoparticles. As a raw material for a metal ion, a metal salt or a metal ion solution can be mentioned. As a raw material for the metal ion, any water-soluble metal compound may be used, and salts of a metal cation and an acid group anion or a metal containing an acid group anion can be used. In addition, metal ions having metal types such as transition metals can be used, but among these metal ions, metal ions of silver, gold, and platinum are good because they are spontaneously reduced at room temperature or heated and converted into nonionic metal nanoparticles. Moreover, when using the obtained colloidal metal solution as an electrically-conductive material, it is preferable to use silver ions from the viewpoint of conductive expression ability or oxidation prevention of the coating film obtained by printing or painting.

The metal nanoparticles (A) manufactured by the above method generate quaternary amine units of the polyalkylene imine by aminate exchange between the added low molecular weight aminate (c) and the polyalkylene imine segment of the protective polymer. The quaternary amine units of the polyalkylene imine produced by aminate exchange between branched polyalkylene imine and aminates are easily separated (decoupled) at low temperature on the surface of the metal nanoparticles forming coordination covalent bond because of the weak binding force. Accordingly, low temperature calcining is possible, the separation is easy and complete, and the protective polymer does not impair the conductivity during the fusion process between the separated metal nanoparticles and thus has good conductive performance. In addition, the low molecular weight amine produced by aminate exchange between the polyalkylene imine and the low molecular weight aminate can also be immobilized on the surface of the metal nanoparticle through a coordinate covalent bond with the metal, thereby contributing to improved dispersion stability.

The dispersion of metal nanoparticles protected by a protective stabilizer, i.e., a metal colloidal aqueous solution or a conductive material obtained by adjusting the aqueous solution with conductive ink for filling in the engraved micropattern, can be calcined at low temperature and has good conductive performance when calcining after filling the micropattern on the substrate. The metal nanoparticles (A) may completely fill the space between the metal particle (B) used together to form a film in a fully filled state, and the metal nanoparticles (A) have a good filling property in the engraved micropattern in a composition used together with the metal particle (B). When the metal nanoparticles are heated and calcined in such a state, as described above, the protective polymer is easily separated (decoupled) from the surface of the metal nanoparticles (A) even at a low temperature, and fusion between the metal nanoparticles (A) proceeds. At this time, the metal nanoparticles (A), during film formation in a fully filled state, fill the space between the metal particles (B) to be used together, maintain a fully filled state and becomes an integrated complete calcined body in a form in which metal nanoparticles (A) connect the metal particles (B), thereby exhibiting better conductive performance.

In the present disclosure, the metal particles (B) having an average particle diameter in a range of 100 to 900 nm are used together with the metal nanoparticles (A) having an average particle diameter in a range of 5 to 50 nm. The metal particles (B) have a significantly larger particle diameter than the metal nanoparticles (A) and are in a stable state that do not need to be protected by a dispersion stabilizer or the like, such as metal nanoparticles. As the metal particles (B), any conventional dry powder known may be used. Examples of the metal particles (B) include metal particles such as gold, silver, copper, and platinum. However, when considering the possibility of forming a micropattern due to good filling properties in the engraved micropattern and to form circuit wiring with low resistance after calcining and good surface smoothness, among metal particles and metal particles having an average particle diameter of 100 to 900 nm, silver particles in the form of thin-film flake are preferred.

In the present disclosure, the metal nanoparticles (A) are used together with the metal particles (B) to suppress aggregation between the metal nanoparticles (A). Since the metal nanoparticles (A) and (B) are formed in a good high-density filled state, a film having good filling properties in an engraved micropattern and better volume resistance in thermal calcining is easily obtained than when only the metal nanoparticles (A) are used. The use ratio of metal nanoparticles (A) and metal particles (B) is not particularly limited, but the mass ratio of the metal nanoparticles (A)/ metal particles (B)=10/90 or 80/20 is preferable. Furthermore, considering that a good volume resistance can be obtained at least at the use ratio of the metal nanoparticles (A), the mass ratio of the metal nanoparticles (A)/ metal particles (B)=15/85 or 60/40 is more preferable.

In preparing the conductive aqueous ink for filling in the engraved micropattern, it is preferable to contain more than 60% of the total of the metal nanoparticles (A) protected by the protective stabilizer and the metal particles (B) based on the mass of the non-volatile substance, and more preferably 70% or more. In order to improve the filling characteristics of the engraved micropattern, a viscosity control method such as adjusting the use ratio of metal nanoparticles (A) and metal particles (B) and adjusting the non-volatile substance during ink composition is effective. To this end, a binder resin is separately used, and since the added binder resin remains as an unnecessary resistance component in the film during calcining and impairs the conductive performance, the binder resin as the third component is preferably adjusted to the minimum necessary amount.

The conductive aqueous ink for filling in an engraved micropattern of the present disclosure is not an oil-based ink mainly composed of an organic solvent like a conventional ink liquid medium but a water-based ink mainly composed of water. By using aqueous ink instead of oil-based ink, a good working environment can be maintained during the printing process, and the risk of fire or explosion can be reduced.

In the present disclosure, the water-soluble solvent (C) has the ability to prepare liquid aqueous ink in order to satisfactorily fill the aqueous metal nanoparticle (A) solution protected by a protective stabilizer composed of a mixture of polymer with branched polyalkylene imine segments and polyoxyalkylene segments and low molecular aminates in the engraved micropattern on the base according to various materials. In the present disclosure, the base material may include high-heat resistant inorganic or organic materials such as glass, metal plates, ceramic, polyimide, etc., to thermoplastic plastics with low heat-resistance and flexibility. Therefore, a water-soluble solvent that can perform calcining at low temperatures without dissolving or swelling the substrate material and has a low risk of fire or explosion without worsening the working environment, such as odor or toxicity, is selected and used.

In the present disclosure, as such a water-soluble solvent C, an alkylene glycol-based or glycerin is used. Examples of the alkylene glycol-based material may include alkylene glycol, which is a liquid at room temperature such as diethylene glycol, diethylene glycol monomethyl ether, diethylene glycol diethyl ether, triethylene glycol, triethylene glycol dimethyl ether, tetraethylene glycol, dipropylene glycol, tripropylene glycol, and the like. Among them, alkylene glycol that starts volatilization at 150° C. or higher such as diethylene glycol, diethylene glycol monoethyl ether, diethylene glycol diethyl ether, triethylene glycol, triethylene glycol monomethyl ether, triethylene glycol dimethyl ether is more desirable, and glycerin is also very good. Water-soluble solvents such as alkylene glycol such as diethylene glycol, diethylene glycol monomethyl ether, diethylene glycol diethyl ether, triethylene glycol, triethylene glycol monomethyl ether triethylene glycol dimethyl ether, and glycerin are excellent in preparing conductive aqueous ink for filling in an engraved micropattern due to low vapor pressure and low volatilization at room temperature, and have good mixing with aqueous metal nanoparticle solution protected by a protective stabilizer composed of a mixture of polymer with polyalkylene imine segments and polyoxyalkylene segments and low molecular aminates and do not cause phase separation. In addition, the water-soluble solvents do not dissolve or swell various thermoplastics, enabling calcining at low temperatures, and do not worsen the working environment due to low odor or toxicity.

The water-soluble solvent (C) may be used in an amount of 5% to 35% by weight based on the total weight of the metal nanoparticles (A) protected by the dispersion stabilizer and metal particles (B), and more preferably 7% to 30% by weight in terms of improving filling characteristics of the engraved micropattern.

In the present disclosure, metal nanoparticles (A) having an average particle diameter in a range of 5 to 50 nm, and metal particles (B) having an average particle diameter in a range of 100 to 900 nm are used together. Examples of such metal nanoparticles (A) and metal particles (B) may include metal particles such as gold, silver, copper, and platinum. In the case of metal nanoparticles (A), conductive ink containing metal nanoparticles such as gold, silver, copper, and platinum can be used as a conductive material ink used in printed electronics, and silver nanoparticles and their ink have been developed in advance for economic feasibility and ease of handling. In addition, in the case of metal particles B, silver particles are good among metal particles such as gold, silver, copper, and platinum, considering that there is no fear of not being filled in the via-hole or trench groove of the engraved micropattern, and a micropattern can be formed, and circuit wiring with good resistance after calcining is possible.

The conductive aqueous ink for filling in an engraved micropattern of the present disclosure is used by filling in the engraved micropattern formed on a base member. As the base member used at this time, for example, a thermoplastic base with low heat resistance such as PET, PEN, polycarbonate, or the like, or a metal or glass base with easy thinning or flexibility may be used. Further, a micropattern such as a via-hole or a trench groove is formed on the base.

When the formed micropattern is a via, the via-hole has a diameter in a range of 0.5 to 10 μm and a depth of the hole in a range of 0.5 to 10 μm. Further, when the formed micropattern is a trench, the trench groove has a width in a range of 0.5 to 10 μm and a depth of the groove in a range of 0.5 to 10 μm.

In the present disclosure, in particular, since metal nanoparticles (A) having an average particle diameter in a range of to 50 nm, and metal particles (B) having an average particle diameter in a range of 100 to 900 nm are used together, the diameter of the via-hole may preferably be in a range of 0.5 to 5 μm, the depth of the hole may preferably be in a range of 0.5 to 5 μm, the width of the trench groove may preferably be in a range of 0.5 to 5 μm, and the depth of the groove may preferably be in a range of 0.5 to 5 μm.

The conductive aqueous ink for filling in the engraved micropattern of the present disclosure fills a micropattern such as a via-hole or a trench groove formed on the base described above and then heats and calcines the micropattern to a temperature at which the metal nanoparticles (A) are fused. Then, the metal nanoparticles (A) in the filled micropattern fill the space between the metal particles (B) used together and maintain a fully filled state. Resulting in a conductor-filled micropattern formed of a completely calcined filler integrated into the form of connecting metal particles (B) with metal nanoparticles (A) may be fabricated. In addition, the above fusion calcining can be performed at a

temperature in a range of 100° C. to 200° C., and in particular, for example, fusion calcining may be performed at a low temperature of 150° C. or less, which may be applied to a thermoplastic base having low heat resistance such as PET, PEN, polycarbonate, or the like, or which may be easily thinned or flexible. The calcining time exhibits sufficient performance in the range of 5 to 60 minutes.

Filling the conductive aqueous ink for filling in the engraved micropattern of the present disclosure into micropatterns such as via-holes or trench grooves formed on a substrate can be performed by any method, for example, a doctor blade filling method, a screen-printing method, a dispenser filling method, a press injection method, and the like.

The conductive aqueous ink for filling in the engraved micropattern of the present disclosure may be prepared by pre-mixing the metal nanoparticle (A) aqueous solution protected by a dispersion stabilizer including a mixture of polymer with the branched polyalkylene imine segment and polyoxyalkylene segment and low molecular aminates, the metal particles (B), and the water-soluble solvent (C) as necessary and then stirring and dispersing at a predetermined shear force.

The conductive aqueous ink for filling in the engraved micropattern of the present disclosure may contain various known additives that improve micropattern filling characteristics, for example, a binder resin, an antifoaming agent, a surfactant, a rheological adjuster, and the like, in a range that does not adversely affect the dispersion stability of the conductive aqueous ink or the performance of the filled wiring after calcining.

In addition, the present disclosure relates to a conductor-filled micropattern fabricated by filling and calcining the above-described conductive aqueous ink composition for filling in the engraved micropattern. In other words, the above-described conductive aqueous ink composition for filling in the engraved micropattern can be filled in an engraved micropattern formed on a thermoplastic base to form circuit wiring, etc., and then calcined at a low temperature of 150° C. or less to form circuit wiring patterns on various bases. As it is simple to mold and is applied to an inexpensive material, it is possible to reduce the weight or size of the base, to be calcined at a lower temperature than in the related art, and to form micropatterns.

In addition, another aspect of the present disclosure relates to a conductive device including a conductor-filled micropattern formed by using the above-described conductive aqueous ink composition for filling in the engraved micropattern. In other words, by filling and calcining the conductive aqueous ink composition for filling in the engraved micropattern of the present disclosure, micropatterns such as circuit wiring are formed on a thermoplastic base with low heat resistance and easy thinning or flexibility, it is possible to provide a conductive device such as lightweight and miniaturized electric and electronic components.

### EXAMPLE

The present disclosure will be described in more detail with Examples below, but the present disclosure is not limited to these Examples.

The analytical instruments and measurement methods used in the following Examples are as follows.

¹H-NMR: Nippon Electronics Co., Ltd., JNM ECP-400, 400 Hz

GPC measurement: Waters Corporation product, ACQUITY APC Core System

TEM measurement: Hitachi Co., Ltd. product, H-7500

SEM measurement: Nippon Electronics Co., Ltd., JSM-6490LV

Surface resistance measurement: Keysight Technology Co., Ltd., U1242C

Solid Content Measurement Method

The content of non-volatile substances, including metal nanoparticles contained in the silver nanoparticle centrifugal agglomeration paste, is measured. About 0.5 g of the agglomeration paste from the silver nanoparticle centrifugation agglomeration paste prepared in the following Examples was dropped on an aluminum dish, pre-dried at 60° C., and then dried at 180° C. for 30 minutes using a hot air dryer to remove residual solvent, and the solid content was measured by calculating the weight difference between the sample before drying and after drying.

Solid content (%)=(weight of the sample after drying/weight of the sample before drying)×100

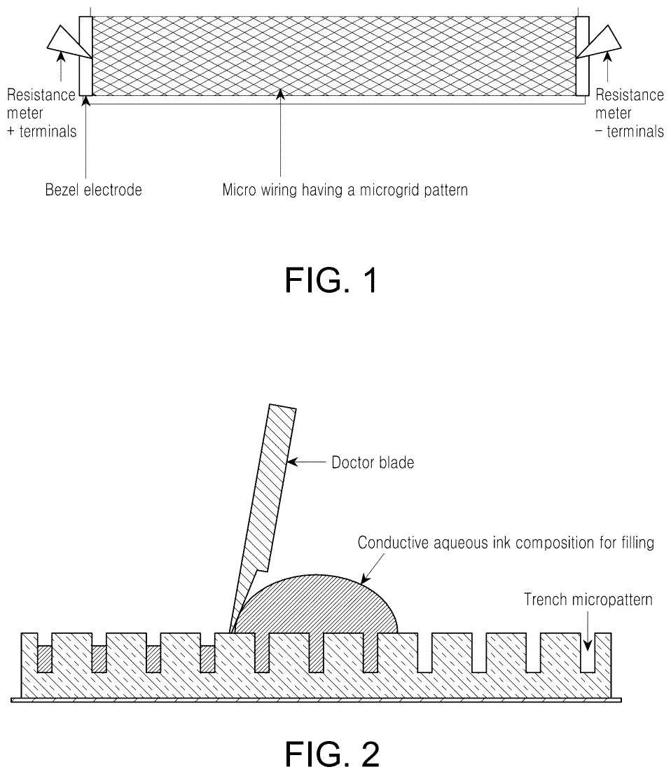

Method for Measuring the State of Filling and Surface Resistance of Micro Wiring Formed on the Engraved Micropattern After mounting the polycarbonate base (FIG. 1) in which the

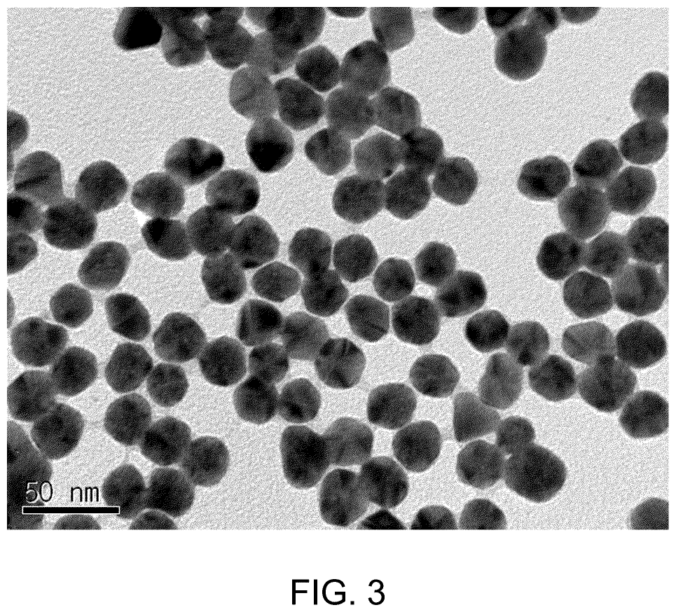

engraved micropattern of the micro lattice lines are used in the following Example on a filling device, conductive aqueous ink for filling is placed on one end above the base. As shown in FIG. 2, a force was applied using a doctor blade to push and move the conductive aqueous ink to the other end, and the groove of the trench micropattern was filled with the conductive aqueous ink. The same filling operation was repeated several times as needed to complete the filling of the grooves of the trench micropattern. After completion of the filling, calcining was performed by heating, and then the metal powder remaining in addition to the filled trench micropattern was wiped (washed) with distilled water. Thereafter, the state of the filling was checked, and the surface resistance was measured using the calcined and wiped micro wiring sample (FIG. 2). Observation of the state of filling of the obtained micro wiring sample was performed using an SEM (manufactured by Japan Electronics Co., Ltd., JSM-6490LV), and the surface resistance (Ω/□) of the micro wiring (C in FIG. 2) was measured by using a surface resistor (product of Keysight Technology, U1242C).

### Preparation Example 1

### Synthesis of Protective Polymer

All of the following reactions were performed under a nitrogen atmosphere.

60.0 g of monomethoxy polyethylene glycol (Mn=2,000) and 420.0 ml of toluene were measured and introduced into a reactor, and after confirming the reaction solution was dissolved by heating to an internal temperature at 60° C. under a stirring speed of 200 rpm, and the internal temperature of the reaction solution is lowered to 18° C. or less. Thereafter, 20.0 ml of a toluene suspension solution of pulverized potassium hydroxide 4.0 was added to the reactor, and it was confirmed that the temperature of the reaction solution was maintained between 18° C. and 25° C. Subsequently, 17.2 g of p-toluenesulfonyl chloride was added to the reaction vessel, and a little later, 60.0 ml of the toluene suspension solution of pulverized potassium hydroxide 12.0 was slowly added, and each time the toluene suspension was added to the reaction vessel, and it was confirmed that the temperature of the reaction solution was maintained between 18° C. and 25° C. Then, 2.0 g of p-toluenesulfonyl chloride was added to the reaction vessel, and then 40.0 ml of a toluene suspension solution of pulverized potassium hydroxide 8.0 was added. Similarly, it was confirmed that the temperature of the reaction solution was maintained between 18° C. and 25° C., and then the reaction solution was further stirred for 30 minutes to be prepared.

In order to filter the reaction solution, filter paper (5 μm) and silica gel or anhydrous magnesium sulfate were placed on a Buchner funnel to prepare filtering, a vacuum pump was connected and then reduced pressure filtration was performed. Filtration under reduced pressure was repeated about 3 times until the filtered reaction mixture became a clear solution.

For the filtered reaction mixture, the solvent was distilled using a rotary evaporator. At this time, the cooling water was maintained at about 5° C., and the temperature of the rotary evaporator bath was maintained at 40° C. so that 50.4 g of tosylate polyethylene glycol monomethyl ether (yield 78%) was prepared.

¹H-NMR (400 MHz) measurement results for the prepared product are as follows.

¹H-NMR (920) measurement result:

δ(ppm)=7.8(d, 2H), 7.2(d, 2H), 4.2(t, 2H), 3.7 to 3.8(m, PEG methylene), 3.5(s, 3H)

Subsequently, a target polymer is prepared by grafting polyethylene glycol to branched polyethyleneimine. All of the following reactions were performed under a nitrogen atmosphere. 380 g of dimethylacetamide was put into the reactor, heated slowly under a stirring speed of 200 rpm, 73.0 g of branched polyethyleneimine (Mn=10,000) was added, and then dissolved, and 48.0 g of tosylate polyethylene glycol monomethyl ether prepared above was added. After dissolution, 100.0 g of dimethylacetamide was added thereto. The temperature of the reaction solution was raised to 120° C. and maintained, and the stirring reaction was maintained for about 6 hours.

After filtering the reaction solution, a solvent such as dimethylacetamide was distilled off using a reduced-pressure solvent removal device.

Then, about 320.0 g of distilled water was added to the reaction vessel to dissolve the reactant product well, and then the aqueous product solution was filtered using a Roca apparatus. At this time, 437.0 g of the prepared polymer product was prepared and stored in a 25% aqueous solution state.

¹H-NMR (400 MHz) measurement results for the prepared product are as follows.

¹H-NMR (920) measurement result:

δ(ppm)=3.5 to 3.6 (m, PEG methylene), 3.2 (s, 3H), 2.3 to 2.7 (m, bPEI ethylene)

GPC measurement result:

Rt=23,586, Mw=16,480

### Preparation Example 2

### Synthesis of Centrifugal Agglomeration Paste of Silver Nanoparticles

All of the following reactions were performed under a nitrogen atmosphere. 284 g of distilled water was put into the reactor, the stirring speed was operated at 100 rpm, 23.04 g of the polymer aqueous solution prepared in Preparation Example 1 was added, 181.2 g of dimethylethanolamine was added, and the reaction solution was heated to reach a temperature of 40° C. After confirming that, the stirring speed was adjusted to 200 rpm. Thereafter, 192 g of distilled water was added to 115.2 g of silver nitrate, and the previously stirred and dissolved aqueous silver nitrate solution began to be dropped over 30 minutes. The amount of the aqueous silver nitrate solution was dropped for 3 minutes, then the drop was stopped for 3 minutes to stir sufficiently to react, and the remaining aqueous nitrate was dropped for 24 minutes. After completion of the dropwise addition of the silver nitrate aqueous solution, the reaction solution was heated, and the stirring reaction was maintained for about 3 hours from the time the temperature reached 50° C. and then cooled to 30° C. After confirming that the temperature had been reached, the reaction was terminated.

In order to purify and separate the silver nanoparticles synthesized in the reaction solution, 800 g of the above synthesis mixture was added to 3,200 g of acetone, stirred for about 5 minutes, and left for a certain time to precipitate and separate the silver nanoparticles. Subsequently, the above precipitation separation solution was added to 1,200 g of acetone, stirred for about 5 minutes, and allowed to stand for a predetermined period of time to precipitate and separate the silver nanoparticles again. After confirming the separation layer, the transparent supernatant solution was separated and removed, and then 4.7 g of the aqueous aminate solution prepared in advance was added to the separated silver nanoparticle solution and stirred. For the preparation of the aminate, 10.0 g of distilled water was added to 73.1 g of diethylamine (bp. 56° C.) using an ice bath, and 101.3 g of an aqueous hydrochloric acid solution (36%) was slowly added, and mixed while stirring to obtain an aqueous aminate mixed solution with a molar ratio of 1:1. In addition, the silver nanoparticle solution to which the aqueous aminate solution was added was centrifuged at 3000 rpm for 10 minutes using a centrifuge to prepare 107.2 g of silver nanoparticle centrifugation agglomeration paste containing 89.0% silver solids.

FIG. 3 shows the TEM measurement results of silver nanoparticles, and it can be confirmed that the silver nanoparticles have an average particle diameter of 23 nm and are monodisperse good crystalline particles.

### Example 1

42.1 g of centrifugal agglomeration paste (non-volatile content 89%) of metal nanoparticles protected with a protective stabilizer composed of a mixture of a polymer with a polyalkylene imine segment and a polyoxyalkylene segment obtained in Preparation Example 2 and a low molecular weight aminate, 4.6 g of glycerin, 4.4 g of distilled water, and 4.4 g of diethylene glycol diethyl ether were put into a container, and pre-mixing was performed while stirring well. A mixture of pre-mixed nanoparticle agglomeration paste was used to remove low boiling point volatile solvents under reduced pressure.

Subsequently, in a mixture of nanoparticle agglomeration paste with low boiling point volatile solvent removed, 37.9 g of metal particles, which are silver monodispersed powder (SP-004SM, dry powder of particulate silver particles with an average particle diameter of 0.4 μm) manufactured by Yunjung Materials Co., Ltd., was added, stirred well, pre-mixed, kneaded and dispersed using a high-speed disperser, and then 0.02 g of a surfactant (KF-351A, product of Shinetsu Silicon Co., Ltd.) was added and dispersed to prepare a conductive aqueous ink for filling in the engraved micropattern.

Then, after mounting the polycarbonate substrate formed with an engraved micropattern on the filling device, a conductive aqueous ink for filling was placed on one end above the substrate, and a doctor blade was used to apply force to push the conductive aqueous ink to the other end and move the ink, and the groove of the trench micropattern was filled. After filling the trench micropattern groove was completed, the filled trench micropattern was calcined at 120° C. for 30 minutes using a heating oven. Subsequently, in addition to the filled trench micropattern, the remaining metal powder was wiped (cleaned) using distilled water.

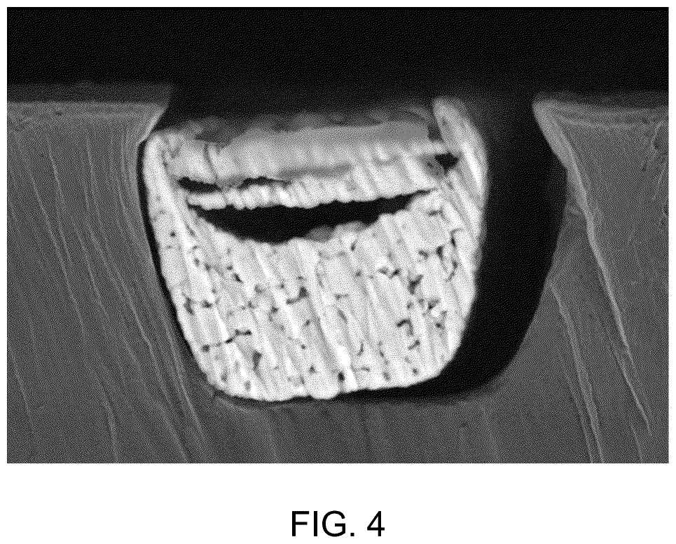

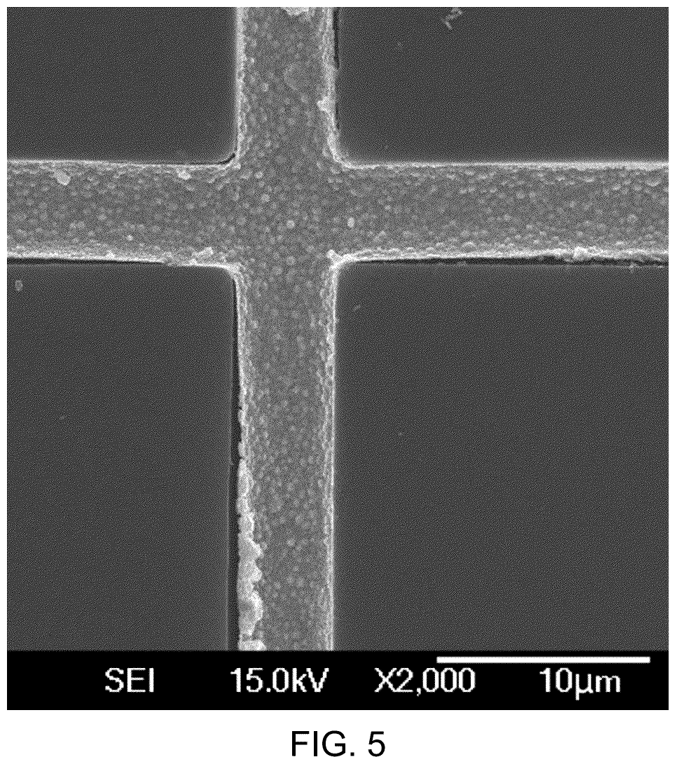

The state of filling of the micropattern of the calcined and wiped micro wirings was confirmed by SEM measurement (see FIGS. 4 and 5), and the surface resistance (Ω/□) was measured by using a surface resistor (Keysight Technology Co., Ltd., U1242C).

### Example 2

A conductive aqueous ink for filling an engraved micropattern was prepared in the same manner as in Example 1, except that 4.4 g of distilled water and 4.4 g of diethylene glycol diethyl ether were set to 3.8 g of distilled water and 0.0 g of diethylene glycol diethyl ether and filled the groove of the trench micropattern twice repeatedly. Then, after filling, calcining, and wiping to the grooves of the trench micropattern, the filling state of the micropattern and the surface resistance of the micropattern wiring were evaluated.

### Example 3

A conductive aqueous ink for filling an engraved micropattern was prepared in the same manner as in Example 1, except that 4.4 g of distilled water, 4.4 g of diethylene glycol diethyl ether, and 37.9 g of metal particles, which are monodispersed silver powder (SP-004SM, dry powder of particulate silver particles having an average particle diameter of 0.4 μm) manufactured by Yunjung Materials Co., Ltd., were set to 8.3 g of distilled water, 8.3 g of diethylene glycol diethyl ether, and 78.2 g of metal particles manufactured by Yunjoong Material Co., Ltd., and filled the groove of the trench micropattern twice repeatedly. Then, after filling, calcining, and wiping to the grooves of the trench micropattern, the filling state of the micropattern and the surface resistance of the micropattern wiring were evaluated.

### Comparative Example 1

A conductive aqueous ink for filling an engraved micropattern was prepared in the same manner as in Example 1, except that 4.4 g of distilled water, 4.4 g of diethylene glycol diethyl ether, and 37.9 g of metal particles, which are monodispersed silver powder (SP-004SM, dry powder of particulate silver particles having an average particle diameter of 0.4 μm) manufactured by Yunjung Materials Co., Ltd., were set to 1.8 g of distilled water, 1.7 g of diethylene glycol diethyl ether, and 3.8 g of metal particles manufactured by Yunjoong Material Co., Ltd., and filled the groove of the trench micropattern four times repeatedly. Then, after filling, calcining, and wiping to the grooves of the trench micropattern, the filling state of the micropattern and the surface resistance of the micropattern wiring were evaluated.

### Comparative Example 2

A conductive aqueous ink for filling an engraved micropattern was prepared in the same manner as in Example 1, except that 4.4 g of distilled water was set to 53.0 g of distilled water and filled the groove of the trench micropattern four times repeatedly. Then, after filling, calcining, and wiping to the grooves of the trench micropattern, the filling state of the micropattern and the surface resistance of the micropattern wiring were evaluated.

### Comparative Example 3

A conductive aqueous ink for filling an engraved micropattern was prepared in the same manner as in Example 1, except that 4.4 g of distilled water and 4.4 g of diethylene glycol diethyl ether, and 4.6 g of glycerin were set to 13.4 g of distilled water, 0.0 g of diethylene glycol diethyl ether, and 0.0 g of glycerin and filled the groove of the trench micropattern four times repeatedly. Then, after filling, calcining, and wiping to the grooves of the trench micropattern, the filling state of the micropattern and the surface resistance of the micropattern wiring were evaluated.

The evaluation results of Examples 1 to 3 and Comparative Examples 1 to 3 are shown in Table 1 and FIGS. 4 to 8 below.

TABLE 1

| | | | | Comparative | Comparative | Comparative |
|---|---|---|---|---|---|---|
| | Example 1 | Example 2 | Example 3 | Example 1 | Example 2 | Example 3 |
| Metal | 42.1 g | 42.1 g | 42.1 g | 42.1 g | 42.1 g | 42.1 g |
| nanoparticles¹⁾ | | | | | | |
| Metal | 37.9 g | 37.9 g | 78.2 g | 3.8 g | 37.9 g | 37.9 g |
| particles²⁾ | | | | | | |
| Distilled water | 4.4 g | 3.8 g | 8.3 g | 1.8 g | 53.0 g | 13.4 g |
| Glycerin | 4.6 g | 4.6 g | 4.6 g | 4.6 g | 4.6 g | — |
| DEGDEE³⁾ | 4.4 g | — | 8.3 g | 1.7 g | 4.4 g | — |
| Surfactant | 0.02 g | 0.02 g | 0.03 g | 0.01 g | 0.02 g | 0.02 g |
| Number of | 1 time | 2 times | 2 times | 4 times | 4 times | 4 times |
| fillings⁴⁾ | | | | | | |
| Filling | ◯ | ◯ | ◯ | Δ | X | X |
| appearance⁵⁾ | | | | | | |
| Surface | 249 | 279 | 287 | 337 | O.L. | O.L. |
| resistance | | | | | | |
| (Ω/□) | | | | | | |

¹⁾Centrifugation agglomerated paste of metal nanoparticles protected with a dispersion stabilizer which is composed of a mixture of a polymer including a branched polyalkylene imine segment and a polyoxyalkylene segment obtained in Preparation Example 2, and a low molecular weight aminate (89% non-volatile content)
²⁾Silver powder manufactured by Yunjoong Materials Co., Ltd. (silver flake-shaped dry powder with an average particle diameter of 400 nm)
³⁾Diethylene glycol diethyl ether
⁴⁾From the viewpoint of filling workability, the number of fillings is performed only up to 4 times
⁵⁾Filling appearance: After filling, calcining, and wiping the trench micropattern (groove width 4 μm, depth 4 μm grid line micropattern, line spacing 300 μm) formed on the polycarbonate base, the filling thickness of the metal silver wiring filled in the trench micropattern was determined by observation of the appearance (SEM measurement). The filling thickness of the wiring was judged as ◯ if the trench micropattern groove was filled by 80% or more and was good, Δ if the trench micropattern groove was filled by 50% or more, and X if the trench micropattern groove was filled by 40% or less and disconnection occurred.

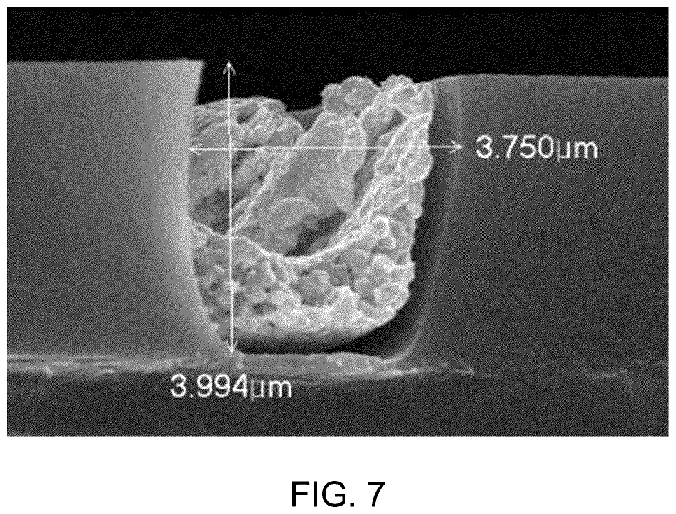

As can be seen from Table 1, the conductive aqueous ink for filling in the engraved micropattern of the present disclosure exhibits good low temperature calcining properties, good filling properties, and good conductivity. Specifically, in the case of Example 1, a conductive aqueous ink for filling was prepared in which the mass ratio of metal nanoparticles (A)/metal particles (B) was the solid content was 85%, and three types of aqueous solvents were included, and the evaluation result after calcining showed good conductivity with a surface resistance of 249 Ω/□ in one time filling. In addition, FIG. 4 shows a SEM image of the cross-section of the micro wiring manufactured according to Example 1, and FIG. 5 shows a SEM image of the surface of the micro wiring. As observed in the SEM image of the cross-section of the micro wiring in FIG. 4, about 90% or more of the microgrooves (width and depth are about 4 μm, see FIG. 7) were filled, and the good filling property was shown as observed in the SEM image of the wiring surface of FIG. 5. In FIGS. 4 and 5, the detached space observed between the calcined metal silver and the inner wall of the polycarbonate trench groove is caused by breaking the base in liquid nitrogen cooling to confirm the SEM observation cross-section.

In the case of Example 2, an aqueous ink for filling was formulated to include two types of aqueous solvents, and in the case of Example 3, the mass ratio of metal nanoparticles (A)/metal particles (B) was 35/65. As a result, the evaluation results after filling and calcining of Examples 2 and 3 showed good conductivity as in Example 1 with surface resistance 279 Ω/□ and 287 Ω/□ in two times filling, and the wiring cross-section and surface SEM photograph showed good filling properties (not shown the drawing).

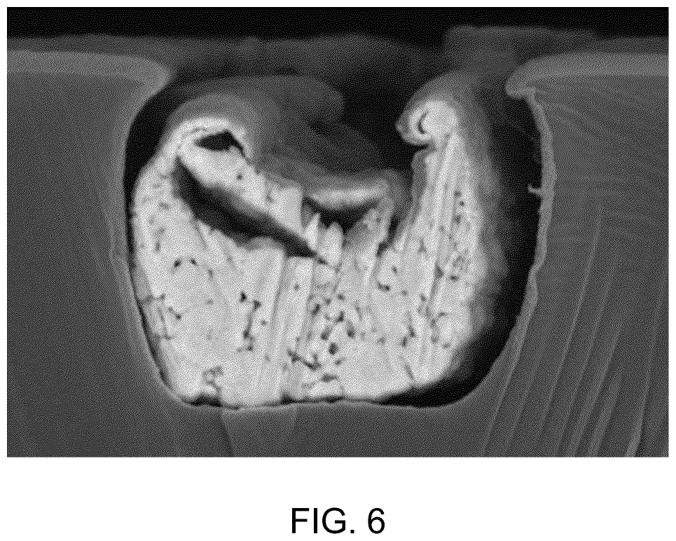

On the other hand, in the case of Example 1, a conductive aqueous ink for filling was prepared in which the mass ratio of metal nanoparticles (A)/metal particles (B) was 90/10, the solid content was 85%, and three types of aqueous solvents were contained. However, the evaluation results after four times filling and calcining Comparative Example 1 showed that the conductivity was lower than those of Examples 1 to 3 with a surface resistance of 337 Ω/□. FIG. 6 shows a SEM image of the cross-section of the micro wiring fabricated according to Comparative Example 1. Referring to FIG. 6, the filling property is also shown as about 60% filling, and it can be confirmed that the filling property is degraded compared to the Example.

In addition, a conductive aqueous ink was prepared for the filling of Comparative Example 2, in which the content of solid composed of metal nanoparticles (A) and metal particles (B) was adjusted to 55%. The ink was evaluated after being filled four times and calcined. However, it was not possible to measure the surface resistance, indicating poor conductivity. FIG. 7 shows an SEM image of the cross-section of the micro wiring fabricated according to

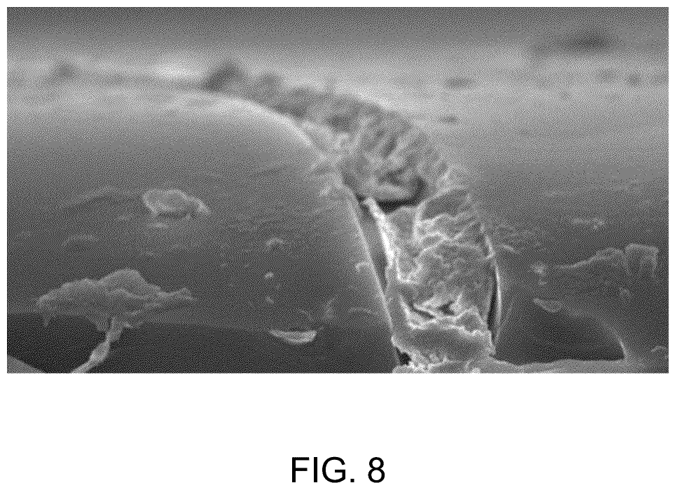

Comparative Example 2, and FIG. 8 shows an SEM image of the cross-section and surface observed together. Referring to FIGS. 7 and 8, it may be confirmed that the filling defect is confirmed by about 40% or less in the SEM observation of FIG. 7, and in the SEM observation of FIG. 8, disconnection of the silver micro wiring is observed, and thus the filling property is significantly lower than in the Example.

In addition, in Comparative Example 3, a conductive aqueous ink for filling was prepared using only distilled water as the aqueous solvent and evaluated after filling and calcining. As a result, the surface resistance could not be measured in the same manner as in Comparative Example 2 in the four times filling, and the SEM observation result was also almost the same as in Comparative Example 2, indicating that the conductivity and filling property was significantly lower than that of Example (not shown the drawing).

As described above, the conductive aqueous ink composition for filling in the engraved micropattern of the present disclosure can exhibit good filling properties and good conductivity as well as good low temperature calcining properties, so the conductive aqueous ink can be easily filled in the engraved micropattern formed on a substrate and can be calcined at a lower temperature compared to the related art to form circuit wiring and the like exhibiting good electrical conductivity. In addition, unlike conventional oil-based ink compositions, the conductive aqueous ink composition for filling does not dissolve or swell general-purpose plastic substrates, has no odor or toxicity, so there is no deterioration of the working environment, and there is no risk of fire or explosion, so it is expected to be highly available in the industry.

1. A conductive aqueous ink composition for filling in an engraved micropattern, the composition comprising:
metal nanoparticles (A) protected with a dispersion stabilizer and having a particle size in a range of 5 to 50 nm; metal particles (B) having a particle size in a range of 100 to 900 nm; and a water-soluble solvent (C) having a boiling point of at least 150° C.;
wherein the metal nanoparticles (A) are protected with the dispersion stabilizer,
wherein the dispersion stabilizer comprises:
a protective polymer composed of a branched polyalkylene imine segment and a polyoxyalkylene segment; and
aminates composed of amine and inorganic acids, and
wherein, when the dispersion stabilizer is separated from the surface of the metal nanoparticles, the metal nanoparticles are activated and surround the metal particles to be fused.

2. The composition of claim 1, wherein a solid content comprising the metal nanoparticles (A) and metal particles (B) is at least 70% by weight, and the water-soluble solvent (C) is at least one selected from alkylene glycol-based solvents and glycerin.

3. The composition of claim 1, wherein the metal nanoparticles (A) and the metal particles (B) are silver nanoparticles and silver particles.

4. The composition of claim 1, wherein the engraved micropattern is a via-hole or a trench, wherein the via-hole has a diameter and depth in a range of 0.5 to 10 μm, and the trench has a width and depth in a range of 0.5 to 10 μm.

5. A conductor-filled micropattern prepared by filling an engraved micropattern formed on a substrate with the composition of claim 1 and calcining the composition in the engraved micropattern.

6. A conductive device comprising the conductor-filled micropattern of claim 5.

7. A conductor-filled micropattern prepared by filling an engraved micropattern formed on a substrate with the composition of claim 2 and calcining the composition in the engraved micropattern.

8. A conductive device comprising the conductor-filled micropattern of claim 7.

9. A conductor-filled micropattern prepared by filling an engraved micropattern formed on a substrate with the composition of claim 3 and calcining the composition in the engraved micropattern.

10. A conductive device comprising the conductor-filled micropattern of claim 9.

11. A conductor-filled micropattern prepared by filling an engraved micropattern formed on a substrate with the composition of claim 4 and calcining the composition in the engraved micropattern.

12. A conductive device comprising the conductor-filled micropattern of claim 11.
